(19) United States
(12) Patent Application Publication
(10) Pub. No.: US 2015/0068887 A1
(43) Pub. Date: Mar. 12, 2015

(54) MANUFACTURING METHOD OF MAGNETORESISTIVE ELEMENT AND MANUFACTURING APPARATUS OF THE SAME

(71) Applicants: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR)

(72) Inventors: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR)

(21) Appl. No.: 14/157,375

(22) Filed: Jan. 16, 2014

Related U.S. Application Data
(60) Provisional application No. 61/875,488, filed on Sep. 9, 2013.

(51) Int. Cl. C23C 14/34

(52) U.S. Cl. CPC C23C 14/3492
USPC 204/192.2; 204/298.11; 204/298.15

(57) ABSTRACT

According to one embodiment, a method of manufacturing a magnetoresistive element includes intermittently exposing a surface of a base substrate to sputter particles from a sputter target, and thereby forming a thin film on the base substrate.

### CROSS-REFERENCE TO RELATED APPLICATIONS

This application claims the benefit of U.S. Provisional Application No. 61/875,488, filed Sep. 9, 2013, the entire contents of which are incorporated herein by reference.

### FIELD

Embodiments described herein relate generally to a manufacturing method of magnetoresistive element used for a magnetoresistive random access memory, and a manufacturing apparatus of the same.

### BACKGROUND

Nowadays, large-capacity magnetoresistive random access memories (MRAMs) using a magnetic tunnel junction (MTJ) element exploiting the tunnel magnetoresistive (TMR) effect have gained attention and raised expectations. In an MTJ element used for an MRAM, one of two ferromagnetic layers (CoFeB) holding a tunnel barrier layer (MgO) therebetween is used as a magnetization fixed layer (reference layer) in which the direction of magnetization is fixed and prevented from changing, and the other is used as a magnetization free layer (storage layer) in which the direction of magnetization is easily reversed. The state where the directions of magnetization of the reference layer and the storage layer are parallel and the state where the directions of magnetization are antiparallel are correlated with binary “0” and “1”, respectively, and thereby information can be stored.

When the directions of magnetization of the reference layer and the storage layer are parallel with each other, the resistance (barrier resistance) of the tunnel barrier layer is lower than that in the case where the directions of magnetization are antiparallel, and has a greater tunnel current. The equation “MR ratio=(resistance in the antiparallel state-resistance in the parallel state)/resistance in the parallel state” holds. Stored information is read out by detecting a change in resistance caused by the TMR effect. Thus, it is preferable that a resistance change rate (MR ratio) caused by the TMR effect is large in reading.

In a method of manufacturing an MTJ element, a sputtering apparatus is generally used for forming MgO as a tunnel barrier layer. However, this method cannot produce MgO with high quality and promoted (001) orientation, and it is difficult to express a high MR ratio through the whole substrate.

### BRIEF DESCRIPTION OF THE DRAWING

FIG. 1 is a schematic diagram illustrating positional relationship between a target and a substrate to be treated.

FIG. 2 is a schematic diagram illustrating results of experiments in dependence of an MR ratio on the position on the substrate.

FIG. 3 is a plan view illustrating an intermittent irradiation region on a substrate to be treated.

FIG. 4 is a cross-sectional view illustrating a schematic structure of a magnetoresistive element manufacturing apparatus according to a first embodiment.

FIG. 5 is a plan view illustrating positional relationship between a substrate to be treated and a substrate shutter.

FIGS. 6A to 6I are cross-sectional views illustrating a process for manufacturing a magnetoresistive element using the apparatus of FIG. 4.

FIG. 7 is a cross-sectional view illustrating a schematic structure of a magnetoresistive element manufacturing apparatus according to a second embodiment.

FIG. 8 is a plan view illustrating arrangement relationship between first and second rotary stages in FIG. 7.

FIG. 9 is a cross-sectional view illustrating a schematic structure of a magnetoresistive element manufacturing apparatus according to a third embodiment.

### DETAILED DESCRIPTION

In general, according to one embodiment, a method of manufacturing a magnetoresistive element comprises: intermittently exposing a surface of a base substrate to sputter particles from a sputter target, and thereby forming a thin film on the base substrate.

### Basic Principle of Embodiments

A basic principle of embodiments will be explained hereinafter, before explanations of the embodiments.

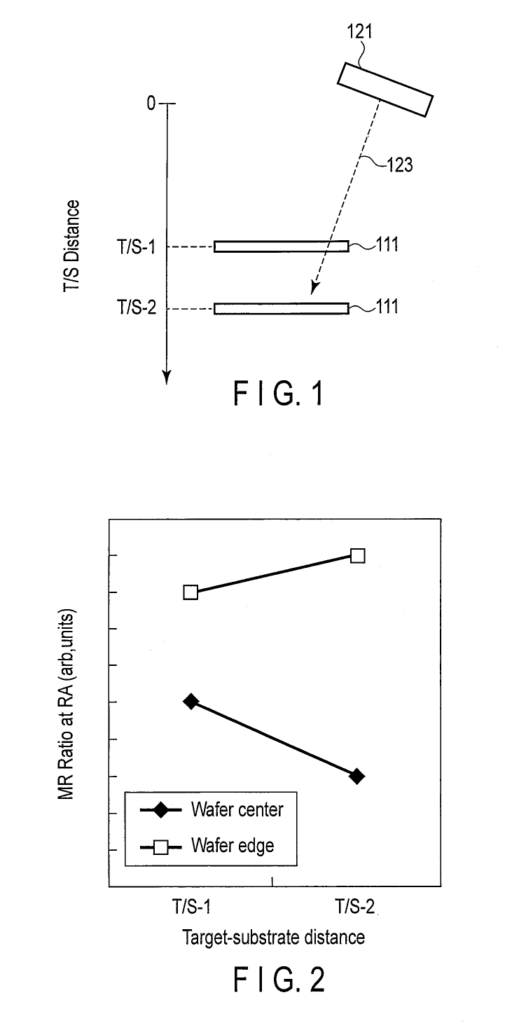

FIG. 1 is a schematic diagram illustrating positional relationship between substrates 111 to be treated and a sputter target 121 formed of MgO, and illustrating distances (T/S) between the target and the substrate. In FIG. 1, the distance (T/S-2) is greater than the distance (T/S-1). The arrow 123 in FIG. 1 indicates a direction of applying sputtering particles and O⁻ ions from the target 121. O⁻ ions are applied together with the sputtering particles to the surface of the substrates 111 to be treated.

FIG. 2 illustrates results of experiments in dependence of the MR ratio on the position on the substrate, in the case where an MgO film is formed by the apparatus of FIG. 1 with the target 121 to produce an MTJ element (magnetoresistive element). In the results, it is inferred that change in the MR ratio depends on a difference in irradiation with O⁻ ions.

As illustrated in FIG. 2, a edge portion of the substrate 111 has a higher MR ratio than that of a central portion of the substrate 111. This tendency holds even when the distance (T/S) is changed. Thus, the MR ratios illustrated in FIG. 2 are mainly caused by a difference in the in-plane position on the substrate 111 to be treated, rather than change in influence of O⁻ ion irradiation according to distance (T/S).

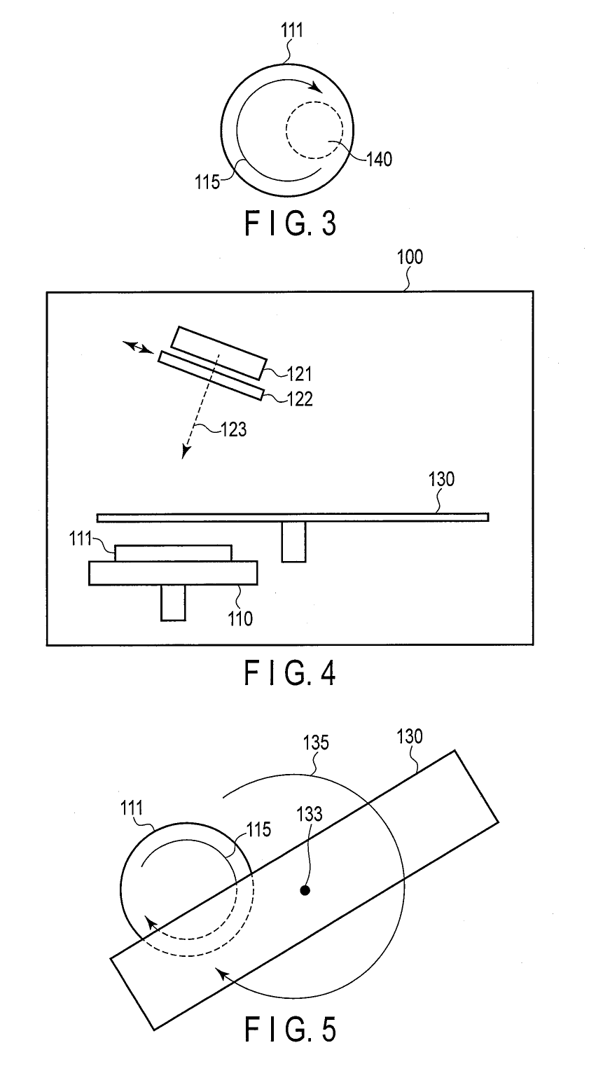

As illustrated in FIG. 3, when the substrate 111 to be treated is rotating in a direction of arrow 115 around the center thereof, an edge portion of the substrate 111 with higher MR ratio corresponds to an intermittent irradiation region of sputtering particles, that is, an intermittent irradiation region 140 of O⁻ ions. Although the central portion of the substrate 111 to be treated is included in part of a region in which O⁻ ions spread, the central portion of the substrate 111 to be treated is continuously irradiated with O⁻ ions, in the structure of an ordinary film formation apparatus. Thus, the MR ratio in the edge portion of the substrate 111 is increased as illustrated in FIG. 2, because MgO is repeatedly damaged and relieved by intermittent irradiation of O⁻ ions, and thereby MgO is formed with higher quality and promoted (001) orientation.

Specifically, the results in FIG. 2 show that expression of high MR ratio requires intermittent irradiation with O⁻ ions emitted from the MgO target. In the present embodiment, an MTJ element having high MR ratio is produced by performing intermittent irradiation.

The following is explanation of method of manufacturing a magnetoresistive element and a manufacturing apparatus of the same according to the present embodiment.

### First Embodiment

FIG. 4 is a cross-sectional view illustrating a schematic structure of a magnetoresistive element manufacturing apparatus according to the first embodiment, and illustrating an example of a sputtering apparatus. FIG. 5 is a plan view illustrating positional relationship between a substrate to be treated and a substrate shutter in FIG. 4.

A first rotary stage 110, on which a substrate 111 to be treated is to be placed, is installed in a film formation chamber 100 used for sputtering. The stage 110 is provided to be rotatable by a motor (not shown), and to rotate the substrate 111 in a direction of the arrow 115 around the center of the substrate 111. The substrate 111 to be treated is used for forming an MTJ element. For example, in the substrate 111, a first ferromagnetic layer, such as CoFeB, is formed on a base substrate.

A sputter target 121 is placed in a position opposing the stage 110 in the chamber 100. Although a normal vector of the center of the target 121 is directed to a central portion of the substrate, it may be shifted from the center of the substrate, since the sputter particles and O⁻ ions going from the target 121 in a direction of arrow 123 spread on the surface of the substrate 111. The target 121 is sputtered by RF electric power applied to a space between the target 121 and the chamber 100 or the stage 110. The target 121 functions as a tunnel barrier layer of the MTJ element, and is formed of, for example, MgO.

A substrate shutter 130 to isolate the substrate 111 and the target 121 from each other is placed in a position between the stage 110 and the target 121 and near the stage 110. The substrate shutter 130 has a length about several times as long as the diameter of the substrate 111, and a width approximately equal to the diameter of the substrate 111. The substrate shutter 130 has an axis 133 in a position distant from the center of the stage 110, and is rotatable in a direction of arrow 135. Rotation of the substrate shutter 130 intermittently isolates the substrate 111 from the target 121.

A target shutter 122 is disposed in a position between the target 121 and the stage 110 and near the target 121. The target shutter 122 prevents damage in the chamber 100 caused by unstable spread of plasma, and contamination of the substrate surface by particles caused by massive discharge of films from the surface of the target, when electric discharge is generated on the surface of the target. The target shutter 122 is controlled independently of the substrate shutter 130.

In the above apparatus, the whole surface of the substrate 111 is intermittently irradiated with sputter particles and O⁻ ions in periods of a second or less, by rotation of the stage 110, on which the substrate 111 is placed, and the substrate shutter 130. Specifically, intermittent O⁻ ion treatment is performed. Although the substrate shutter 130 may be driven to perform straight-line motion or arc-like reciprocal motion, it is preferable to adopt rotary motion to perform high-speed driving with less load on the driving motor and less malfunction frequency.

To start film formation in the above apparatus, the target 121 is sputtered by RF discharge in a state where the target shutter 122 is closed. By the sputtering, sputter particles are discharged from the target 121, and O⁻ ions are also discharged. Then, after sputtering becomes stable, the target shutter 122 is opened, and sputtering film formation is started.

When sputtering film formation is started, the stage 110 is rotated, and the substrate shutter 130 is rotated in advance at a speed of about 100 rpm. Since the substrate 111 is rotated by rotation of the stage 110, the whole surface of the substrate 111 is uniformly irradiated with the sputter particles and O⁻ ions. In addition, since the substrate shutter 130 is rotating, the whole surface of the substrate 111 is intermittently irradiated with the sputter particles and O⁻ ions from the target 121. Since O⁻ ions are intermittently applied, MgO formed on the substrate 111 is damaged and relieved repeatedly, and MgO with higher quality and promoted (001) orientation is formed.

Although the rotational speed of the substrate shutter 130 is not specifically limited, too low a speed reduces the effect obtained by repeated damage and relief, and thus certain high speed should be adopted. Experiments performed by the inventors of the present invention proved that sufficient rotational speed of the substrate shutter 130 was speed with periods of a second or more.

The sputtering apparatus is not always limited to RF sputtering, but DC sputtering may be adopted. In either of RF sputtering and DC sputtering, the surface of the substrate is exposed to damage caused by sputter plasma. By subjecting the whole surface of the substrate to intermittent treatment as in the present embodiment, the film on the surface of the substrate is repeatedly damaged and restored, arrangement of atoms forming the film is optimized, and the property of the film is improved on the whole surface of the substrate. In the above treatment, the damage source is, for example, O⁻ or recoil sputter gas atoms in RF sputtering, and electrons or recoil sputter gas atoms in DC sputtering.

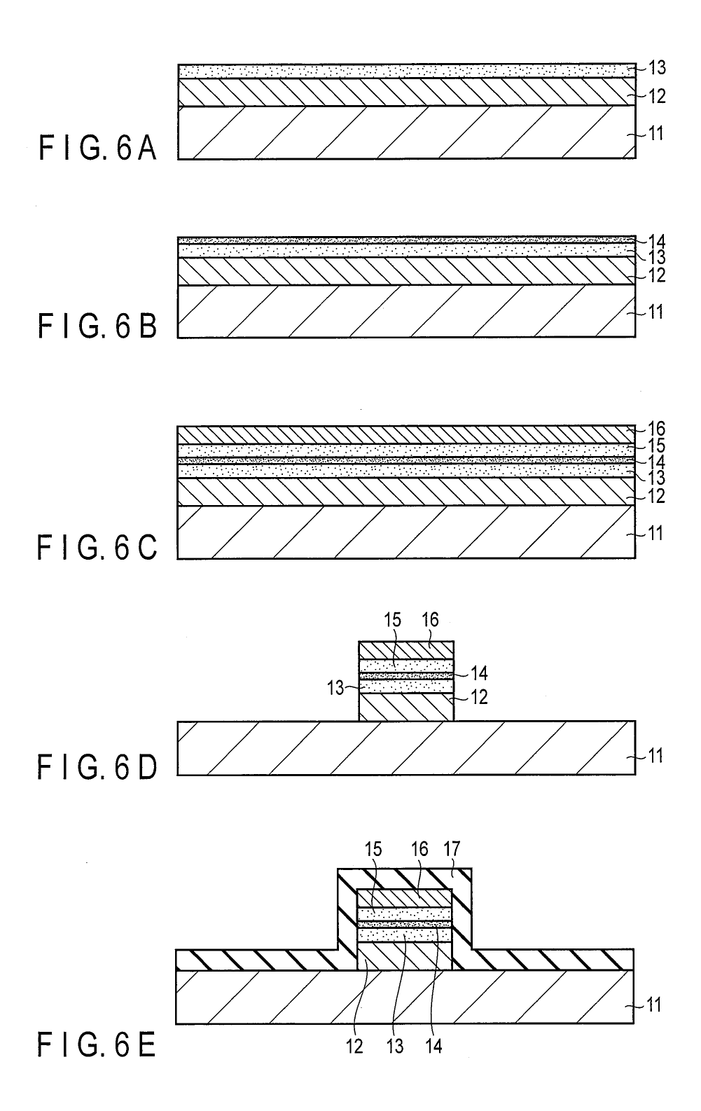

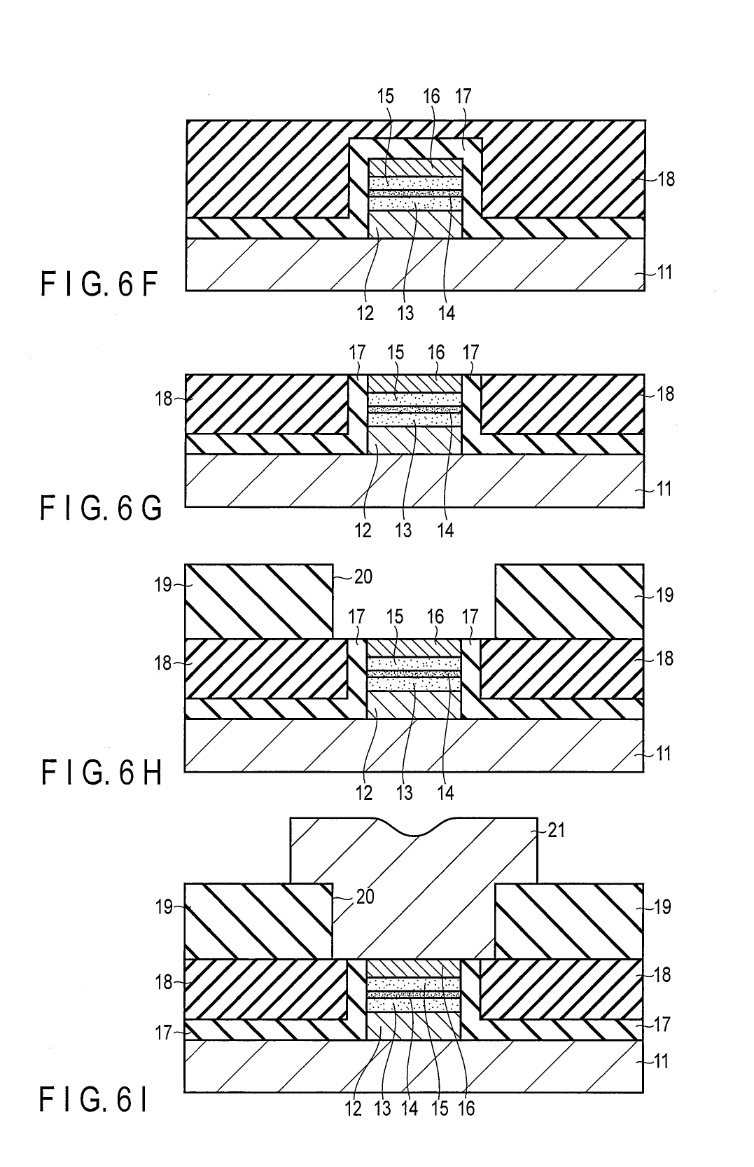

Next, a method of manufacturing magnetoresistive element using the sputtering apparatus of FIG. 4 will be explained hereinafter, with reference to step cross-sectional views of FIGS. 6A to 6I.

First, as illustrated in FIG. 6A, an underlayer 12 formed of Ru and having a thickness of 2 nm, and a CoFeB layer (first ferromagnetic layer) 13 having a thickness of 2 nm are formed on a lower interconnect layer 11 formed of Ta and having a thickness of 5 nm. The method for forming the underlayer 12 and the first ferromagnetic layer 13 may be any of sputtering, molecular beam epitaxy (MBE), atomic layer deposition (ALD), and chemical vapor deposition (CVD), or another method. The underlayer 12 may also serve as a lower electrode layer or a reference layer. The ferromagnetic layer 13 may be used as a reference layer or a storage layer.

Next, as illustrated in FIG. 6B, an MgO tunnel barrier layer 14 is formed. The MgO tunnel barrier layer 14 has been subjected to intermittent irradiation with O⁻ ions over the whole substrate by the manufacturing apparatus, to which the present embodiment is applied.

Specifically, the structure illustrated in FIG. 6A is used as a substrate to be treated, and placed on the stage 110 of the apparatus illustrated in FIG. 4. Then, the substrate shutter 130 is rotated together with rotation of the stage 110 to subject the MgO target 121 to RF sputtering, and thereby an MgO layer (tunnel barrier layer) 14 having a thickness of 1 nm is formed on the ferromagnetic layer 13. By intermittent O⁻ ion irradiation using the substrate shutter 130, the MgO layer 14 is repeatedly damaged and relieved, and thereby has high quality and promoted (001) orientation.

Next, as illustrated in FIG. 6C, a CoFeB layer (second ferromagnetic layer) 15 having a thickness of 2 nm is formed on the tunnel barrier layer 14, and an upper layer 16 formed of Ta is formed thereon. The ferromagnetic layer 105 may be used as a storage layer or a reference layer. The upper layer 106 may be used as a etching mask, a reference layer, a surface protective layer, or an upper interconnect connection layer.

Next, as illustrated in FIG. 6D, the upper layer 16, the second ferromagnetic layer 15, the tunnel barrier layer 14, the first ferromagnetic layer 13, and the underlayer 12 are successively and selectively etched by ion milling or the like, to form a laminate structure part formed of the underlayer 12 to the upper layer 16 with an island shape.

Then, as illustrated in FIG. 6E, an insulation layer 17 to protect an MTJ part is formed in the next step, by sputtering, CVD, or ALD. The insulation layer 17 is, for example, SiN, SiOx, MgO, or AlOx, and formed on an upper surface and side surfaces of the MTJ part and an exposed upper surface of the lower interconnect layer 11.

Next, the lower interconnect layer 11 is selectively etched by, for example, reactive ion etching (RIE). The processed portions of the lower interconnect layer 11 are located in the front part and the rear part of FIG. 6E, and not shown. In the etching, the MTJ part is protected by the insulation layer 17 illustrated in FIG. 6E.

Then, as illustrated in FIG. 6F, an insulation layer 18 is formed on the insulation layer 17 by sputtering or CVD or the like, to bury the MTJ part. The insulation layer 18 is, for example, SiOx.

Next, as illustrated in FIG. 6G, the insulation layer 18 is subjected to etchback by chemical mechanical polishing (CMP) or gas phase etching, to expose an upper surface of the upper layer 16 of the MTJ part.

Then, as illustrated in FIG. 6H, an insulation layer 19 is formed on the MTJ part and the insulation layer 18, and then a contact hole 20 is opened on the MTJ part. The insulation layer 19 is, for example, SiOx.

Next, as illustrated in FIG. 61, an upper interconnect layer 21 formed of Al or Al—Cu is formed, and subjected to selective etching to have an interconnect pattern by RIE or the like. Thereby, a magnetoresistive element is finished.

As described above, according to the present embodiment, the whole substrate is intermittently exposed to sputter particles and O⁻ ions in a region of a normal vector direction of the center of the MgO target, when the MgO tunnel barrier layer 14 of the magnetoresistive element is formed. Thereby, MgO of the whole substrate is repeatedly subjected to damage and relief caused by O⁻ ions, and obtains improved quality. Then, the (001) orientation of MgO is promoted, and thereby high MR ratio is expressed over the whole substrate.

Thus, the present embodiment enables production of magnetoresistive elements having excellent property as memory elements of MRAMs, which is extremely effective. The sputtering apparatus thereof is obtained by only providing a conventional apparatus with the rotatable substrate shutter 130, and can be achieved without large change in a conventional apparatus.

### Second Embodiment

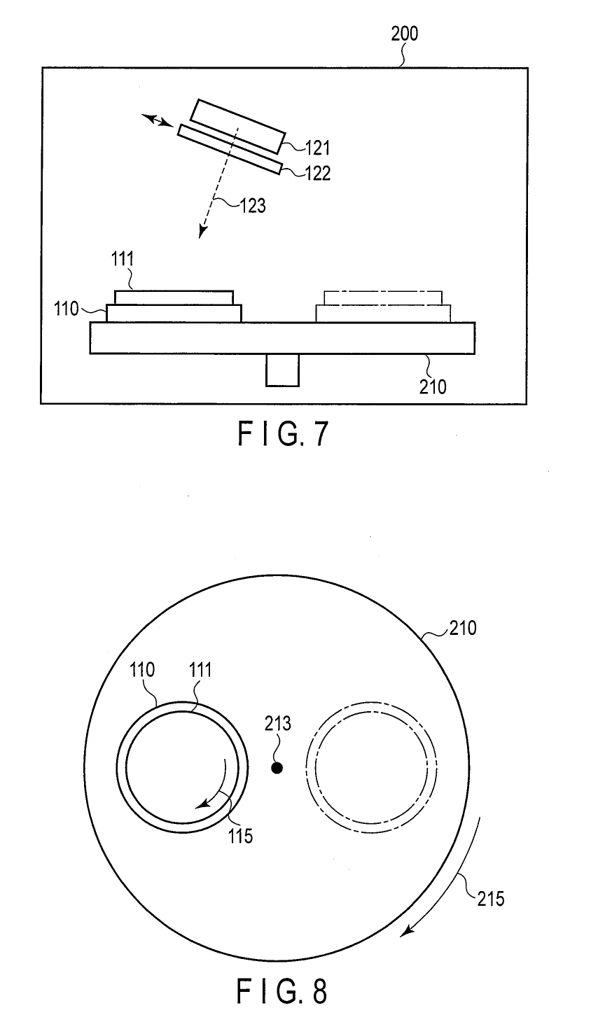

FIG. 7 is a cross-sectional view illustrating a schematic structure of a magnetoresistive element manufacturing apparatus according to a second embodiment, and illustrating an example of a sputtering apparatus. FIG. 8 is a plan view illustrating positional relationship between a substrate to be treated and a substrate shutter in FIG. 7.

In the present embodiment, a second rotary stage 210 is installed in a chamber 100, instead of the substrate shutter 130 illustrated in FIG. 4. In addition, a first rotary stage 110 is placed in a region on the stage 210, which is shifted from the center of the stage 210. Specifically, the second rotary stage 210 has a diameter at least twice as large as a diameter of the first rotary stage 110, and rotates in a direction of arrow 215 on an axis 213 that is distant from the center of the first rotary stage 110. Thereby, the substrate 111 to be treated rotates on its own axis by rotation of the stage 110, and revolves (around the axis 213) by rotation of the stage 210.

When the substrate 111 to be treated revolves (around the axis 213), the surface of the substrate 111 to be treated is exposed to sputter particles and O⁻ ions from the target 121 in a position where the substrate 111 is opposed to the target 121, but not exposed to sputter particles or O⁻ ions in other positions. Specifically, the whole surface of the substrate 111 to be treated is intermittently irradiated with O⁻ ions from the target 121, like the case where the substrate shutter 130 is rotated. Although the second rotary stage 210 may be driven to reciprocally move in a straight-line direction, it is preferable to adopt rotary motion to perform high-speed driving with less load on the driving motor and less malfunction frequency. Although the rotational speed of the second rotary stage 210 is not specifically limited, the rotational speed is preferably a speed at which the stage 210 performs one rotation in a second or less, like the rotational speed of the substrate shutter 130.

The specific process of manufacturing the MTJ element using the present apparatus is similar to the first embodiment, as illustrated in FIGS. 6A to 6I.

As described above, according to the present embodiment, the second rotary stage 210 is rotated together with the first rotary stage 110, and thereby the whole surface of the substrate 111 can be intermittently exposed to a region of a normal vector region of the center of the MgO target, like the first embodiment. Thus, high MR ratio can be obtained through the whole substrate, and it is possible to manufacture magnetoresistive elements having excellent property for MRAMs, in the same manner as the first embodiment.

### Third Embodiment

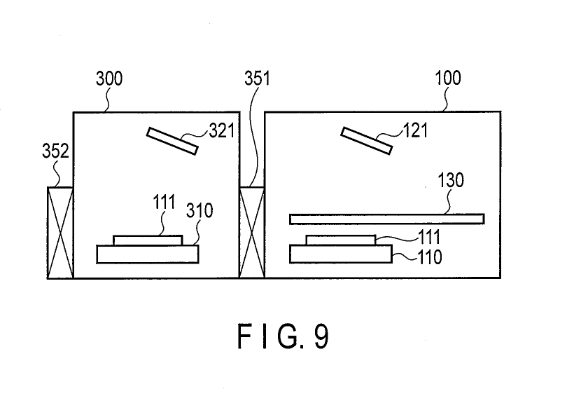

FIG. 9 is a cross-sectional view illustrating a magnetoresistive element manufacturing apparatus used for a third embodiment.

The apparatus includes a ferro-magnetic layer film-formation device, in addition to a film-formation device for forming a tunnel barrier layer of an MTJ element.

A film-formation chamber 300 of a DC sputtering apparatus for a ferromagnetic layer is installed adjacent to the film-formation chamber 100 of the RF sputtering apparatus described in the first or second embodiment.

A rotary stage 310 to place a substrate 111 to be treated on is installed in the chamber 300, and a sputter target 321 is placed in a position opposed to the stage 310. The chambers 100 and 300 are connected to each other by a gate valve 351. In addition, the chamber 300 is provided with a gate valve 352 to take out and put in the substrate 111 to and from the outside (atmosphere).

The ferromagnetic layer film-formation device is not limited to a DC sputtering apparatus, but may be an MBE device, an ALD device, or a CVD device.

In the present embodiment, the substrate 111 to be treated is conveyed into the chamber 300 and placed on the stage 310, in a state where the gate valve 352 is opened. Then, after the gate valve 352 is closed, the first ferromagnetic layer 13 illustrated in FIG. 6A is formed by sputtering. The substrate 111 has a structure in which the underlayer 12 is formed on the lower interconnect layer 11. The underlayer 12 may be formed in the chamber 300 before the ferromagnetic layer 13 is formed, by preparing a target for the underlayer 12 in the chamber 300.

Next, the gate valve 351 is opened, and then the substrate 111 is conveyed into the chamber 100 and placed on the stage 110. Then, after the gate valve 351 is closed, the tunnel barrier layer 14 illustrated in FIG. 6B is formed by sputtering, while the stage 110 and the substrate shutter 130 are rotated at high speed.

After the tunnel barrier layer 14 is formed, the gate valve 351 is opened, and then the substrate 111 is returned into the chamber 300 and placed on the stage 310. Then, after the gate valve 351 is closed, the second ferromagnetic layer 15 illustrated in FIG. 6C is formed by sputtering. The steps after this are similar to the steps illustrated in FIGS. 6D to 6I.

As described above, according to the present embodiment, it is possible to successively form an MTJ film, in which the tunnel barrier layer 14 with high quality and promoted (001) orientation is held between the first and second ferromagnetic layers 13 and 15. It is thus possible to produce MTJ elements with high MR ratio.

### Modification

The present invention is not limited to the above embodiments.

Although the substrate shutter and the second rotary stage are rotated at rotational speed of 100 rpm in the embodiments, their rotational speeds are not limited. However, too low rotational speed reduces the effect obtained by repeatedly damaging and relieving MgO, and they preferably performs one rotation per second or less.

In addition, the size of the substrate shutter in the first embodiment is not necessarily several times as large as the diameter of the substrate, but it suffices that the size of the substrate shutter is larger than the diameter of the substrate. The method for driving the substrate shutter is not limited to rotation, but may be any method that enables the shutter to be put into or taken out of the space between the target and the substrate at high speed.

Although single-wafer processing apparatuses are explained in the embodiments, the present invention is not limited to them, but may be applied to a batch apparatus that simultaneously performs treatment for a plurality of substrates to be treated. For example, in the apparatus illustrated in FIG. 7, a plurality of substrates 111 to be treated are placed on the second rotary stage 210, and thereby tunnel barrier layers can be simultaneously formed on the respective substrates 111.

In addition, the target material is not limited to MgO, but may be any metal that can function as a tunnel barrier layer. For example, Al₂O₃ may be used as the target material. The target material is not limited to a simple substance thereof, but may be a material including one of them as a main component.

The present invention is not limited to formation of a tunnel barrier layer, but is applicable to formation of a ferromagnetic layer. Application of the present invention to formation of a ferromagnetic layer such as CoFeB reduces plasma damage. As a result, the layer has improved flatness, and increase in pressure resistance of MgO and reduction in variations are achieved when MgO or the like is formed on CoFeB. In addition, the MR ratio is improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetoresistive element, comprising:
intermittently exposing a surface of a base substrate to sputter particles from a sputter target by sputtering, and thereby forming a thin film on the base substrate.

2. The method of claim 1, wherein
the forming the thin film includes intermittently isolating the first ferromagnetic layer from the target by a rotatable substrate shutter.

3. The method of claim 2, wherein
the intermittent isolation by the substrate shutter is performed while the substrate is rotated on the center of the substrate serving as an axis

4. The method of claim 2, wherein
the intermittent isolation by the substrate shutter is performed in periods of one second or less.

5. The method of claim 1, wherein
the forming the thin film includes causing the substrate to revolve around a position distant from the substrate, while the substrate is rotated on the center of the substrate serving as an axis.

6. The method of claim 1, wherein
a surface of the base substrate is intermittently exposed to the sputter particles from the target in periods of one second or less, by revolution of the substrate.

7. The method of claim 1, wherein
the base substrate includes an uppermost layer being a first ferromagnetic layer, and the method further comprises forming a tunnel barrier layer as the thin film on the first ferromagnetic layer, and forming a second ferromagnetic layer on the tunnel barrier layer.

8. The method of claim 7, wherein
a material including MgO or Al₂O₃ as a main component is used as the target.

9. The method of claim 7, wherein
a film formation apparatus to form the first and second ferromagnetic layers is provided separately from a film formation apparatus to form the tunnel barrier layer, and the substrate is moved between the film formation apparatuses in accordance with a film formation order of the first ferromagnetic layer, the tunnel barrier layer, and the second ferromagnetic layer.

10. A magnetoresistive element manufacturing apparatus, comprising:
a chamber used for sputtering film formation;
a first rotary stage installed in the chamber and to place a substrate to be treated on;
a sputter target installed in the chamber, and disposed opposite to the stage;
a mechanism sputtering the target; and
a substrate shutter disposed between the target and the stage, and intermittently isolating the substrate from the target.

11. The apparatus of claim 10, wherein
the substrate shutter intermittently isolates the stage and the target from each other by rotary motion.

12. The apparatus of claim 10, further comprising:
a target shutter located in a position closer to the target than the substrate shutter.

13. The apparatus of claim 10, wherein
the substrate shutter intermittently isolates the substrate in periods of one second or less.

14. The apparatus of claim 10, wherein
the substrate includes an uppermost layer being a first ferromagnetic layer, and the target includes MgO or Al₂O₃ as a main component.

15. The apparatus of claim 10, wherein
the mechanism applies high-frequency electric power between the target and the chamber or the stage.

16. A magnetoresistive element manufacturing apparatus, comprising:
a chamber used for sputtering film formation;
a first rotary stage installed in the chamber and to place a substrate to be treated on;
a sputter target installed in the chamber, and disposed opposite to the stage;
a mechanism sputtering the target; and
a second rotary stage to place the first rotary stage on, the second rotary stage causing the substrate around a position different from a rotational center position of the first rotary stage, and exposing a surface of the substrate to sputter particles from the target.

17. The apparatus of claim 16, further comprising:
a target shutter located in a position closer to the target than the substrate shutter.

18. The apparatus of claim 16, wherein
the second rotary stage performs one rotation per second or less.

19. The apparatus of claim 16, wherein
the substrate includes an uppermost layer being a first ferromagnetic layer, and the target includes MgO or Al₂O₃ as a main component.

20. The apparatus of claim 16, wherein
the mechanism applies high-frequency electric power between the target and the chamber or the stage.
